(19) United States
(12) Patent Application Publication
(10) Pub. No.: US 2013/0249094 A1
(43) Pub. Date: Sep. 26, 2013

(54) METHOD OF PREPARING TRANSPARENT CONDUCTING OXIDE FILMS

(71) Applicants: Hansong Cheng, Singapore (SG); Guo Qin Xu, Singapore (SG)

(72) Inventors: Hansong Cheng, Singapore (SG); Guo Qin Xu, Singapore (SG)

(73) Assignee: National University of Singapore, Singapore (SG)

(21) Appl. No.: 13/990,779

(22) PCT Filed: Nov. 28, 2011
(86) PCT No.: PCT/SG2011/000419

§ 371 Date: May 30, 2013

Related U.S. Application Data
(60) Provisional application No. 61/418,804, filed on Dec. 1, 2010.

(51) Int. Cl. H01L 31/18; H01L 51/00

(52) U.S. Cl. CPC H01L 31/1884; H01L 51/0021
USPC 257/749; 438/609

(57) ABSTRACT

The present invention discloses a method of preparing a transparent conducting oxide (TCO) film comprising the steps of: applying surface modified TCO nanoparticles onto a surface of a substrate; and cross-linking the surface modified TCO nanoparticles. The present invention also provides a transparent conducting oxide film prepared according to the method.

### TECHNICAL FIELD

The present invention relates to a method of preparing a transparent conducting oxide film. The present invention also relates to a transparent conducting oxide film obtained from the method.

### BACKGROUND

Nanostructured transparent conducting oxides (TCOs) are essential in optoelectronics. Demand for thin films (about 200-500 nm thick) and device fabrication of TCOs onto flexible substrates to be used in emerging applications such as OLEDs, flat panel display and thin film solar cells has been increasing rapidly in recent years. For example, indium-tin oxide (ITO) has become the dominant transparent electrode material for flat panel displays and organic photovoltaic devices.

Thin, lightweight, unbreakable, and inexpensive continue to be the desirable attributes in electronics, especially in portable electronics. Although significant progress on deposition of TCO nanoparticles on glass substrates has been made in the last few years, these attributes are increasingly difficult to achieve, preventing the device performance from advancing to the next level. To this end, plastic substrates made of organic polymers are required. The plastic substrates, in principle, can be made to be unbreakable, conformable, bendable, rollable, and cloth-like and thus are well-suited for portable electronic applications. They also facilitate a high volume roll-to-roll processing operation, which would potentially lower production costs and capital expenditures for comparable greenfield sites and are thus essential for emerging applications such as thin film solar cells and OLED lighting.

As an industry standard TCO for high work function electrodes, ITO nanoparticles have been successfully deposited on flexible substrates by physical vapour deposition (PVD) techniques. However, the film does not display the required properties, such as low resistivity (or sheet resistance ˜5 ohm/square) and high stability, for applications in flexible optoelectronics. The low electrical resistance requirement of the ITO film can be met either by annealing the ITO film at high temperature or by increasing the film thickness. Unfortunately, annealing the ITO film at high temperature is not desirable as it degrades the properties of the flexible substrates. Increasing ITO film thickness is not desirable either because it induces cracks in the film, thereby creating paths for short-circuiting current and significantly reducing light transmittance. Similar performance of other TCO nanoparticles is also expected.

The currently available technology to deliver TCO thin films at relatively low temperatures (˜150° C.) is atomic layer deposition (ALD) technique or sputtering in high vacuum for some niche applications. However, their applicability and scalability are both limited and the processes are expensive since ALD relies solely on specialty organometallic precursors to deliver the metallic elements followed by oxidation with O₃, H₂O₂ or plasma O₂. In the case of sputtering in high vaccum, the process is expensive and also requires annealing to obtain the required resistivity in the case of flexible substrates.

There is therefore a need for an improved process.

### SUMMARY OF THE INVENTION

The present invention seeks to address at least one of the problems in the prior art, and provides an improved method for preparing a thin transparent conducting oxide (TCO) film.

According to a first aspect, there is a provided a method of preparing a transparent conducting oxide (TCO) film, comprising:
applying surface modified TCO nanoparticles onto a surface of a substrate; and
cross-linking the surface modified TCO nanoparticles.

The substrate onto which the surface modified TCO nanoparticles are applied may be any suitable substrate. For example, the substrate may be a plastic or glass substrate.

The applying of the surface modified TCO nanoparticles onto a surface of a substrate may be by any suitable method. For example, the applying may be by spin coating, spray coating, roller coating, chemical deposition, physical vapour deposition, or a combination thereof.

The cross-linking may be by any suitable method. According to a particular aspect, the cross-linking may be by cycloaddition, photochemical reaction and/or thermal reaction.

The surface modified TCO nanoparticles applied onto the surface of the substrate may be prepared by any suitable method. For example, the surface modified TCO nanoparticles may be prepared by reacting TCO nanoparticles with at least one unsaturated moiety. Therefore, according to a particular aspect, the method may further comprise reacting TCO nanoparticles with at least one unsaturated moiety to provide the surface modified TCO nanoparticles. In particular, the reacting may comprise heating the TCO nanoparticles with the unsaturated moiety. The heating may be carried out at any suitable temperature. For example, the heating may be carried out at a temperature of 50-250° C.

The TCO nanoparticles may be any suitable TCO nanoparticle. In particular, the TCO nanoparticles may be indium tin oxide (ITO) nanoparticles. The TCO nanoparticles may be of a suitable size. For example, the TCO nanoparticles may comprise at least one dimension of size ≦200 nm. In particular, the TCO nanoparticles may comprise at least one dimension of size 3-100 nm. Even more in particular, the TCO nanoparticles may comprise at least one dimension of size 3-25 nm.

Any suitable unsaturated moiety may be used for the purposes of the present invention. According to a particular aspect, the unsaturated moiety may be a moiety which comprises one or more pi-bond. For example, the unsaturated moiety may be optionally substituted alkene, alkyne, diene, an aromatic compound, a heteroaromatic compound, or a combination thereof. The unsaturated moiety may also be represented by the formula (I) or (II):

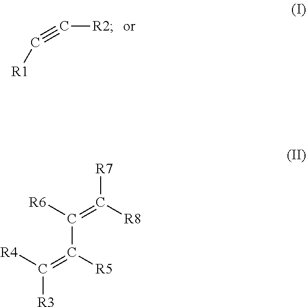

wherein each R1, R2, R3, R4, R5, R6, R7, R8 may be the same or different, and may be selected from the group consisting of: H, an aliphatic species, an aromatic species and a halide.

The aliphatic species may be any suitable species. For example, the aliphatic species may be CH₃−. The aromatic species may be any suitable species. For example, the aliphatic species may be C₆H₅−. The halide may be any suitable halide. For example, the halide may be Cl.

Even more in particular, the unsaturated species may be acetylene, ethylene, butadiene, or a combination thereof.

According to a particular aspect, the method may further comprise heating the TCO nanoparticles prior to reacting them with the at least one unsaturated moiety. The heating may be carried out at a suitable temperature. For example, the heating may be carried out at a temperature of 250-550° C. In particular, the heating may be carried out at a temperature of 300-350° C. Even more in particular, the heating may be carried out at a temperature of about 350° C.

According to a second aspect, the present invention provides a transparent conducting oxide (TCO) film obtained from the method according to the first aspect. The present invention further provides an article of manufacture comprising the TCO film obtained from the method according to the first aspect. The article of manufacture may be any suitable article of manufacture which requires a TCO film. In particular, the article of manufacture may be, but not limited to, an organic light-emitting diode (OLED), a flat panel display, thin film solar cells, a flexible display, a touch panel, a transparent electrode for optoelectronic devices, a heat-reflecting mirror, or a transparent heating element.

There is also provided a transparent conducting oxide (TCO) nanoparticle including a surface modification by an unsaturated moiety. The TCO nanoparticle including the surface modification may be for use in a method of preparing a transparent conducting oxide film. For example, the method may be according to the first aspect of this invention. The unsaturated moiety may be any suitable moiety such as that described above in relation to the first aspect of the present invention.

### BRIEF DESCRIPTION OF THE DRAWINGS

In order that the invention may be fully understood and readily put into practical effect there shall now be described by way of non-limitative example only exemplary embodiments, the description being with reference to the accompanying illustrative drawings. In the drawings:

FIG. 1 is a flow chart showing the general method of preparing a transparent conducting oxide film according to the present invention;

FIG. 2 shows a cycloaddition between a surface oxygen dimer of an ITO nanoparticle and an acetylene molecule according to one embodiment of the present invention;

FIG. 3 shows cycloaddition between two C═C bonds of two neighbouring ITO nanoparticles prepared according to one embodiment of the method of the present invention;

FIG. 4 shows: (a) SEM image of ITO nanoparticles prepared according to one embodiment of the method of the present invention at a magnification of 100,000, (b) SEM image of the ITO nanoparticles of (a) at a magnification of 200,000, (c) XRD pattern of the ITO nanoparticles of (a);

FIG. 5 shows the TGA-DTA analysis (weight of sample: 9.5819 mg; ramping at 10° C./min to 800° C.) of ITO nanoparticles prepared according to one embodiment of the method of the present invention;

FIG. 6 shows the TGA-DTA analysis (weight of sample: 12.7680 mg) of ITO nanoparticles prepared according to one embodiment of the method of the present invention after being subjected to pre-treatment conditions;

FIG. 7 shows the TGA analysis of surface-modified ITO nanoparticles in which the surface modification is carried out at (a) 50° C. (weight of sample: 10.4940 mg; ramping at 10° C./min to 800° C.), (b) 100° C. (weight of sample: 10.1442 mg; ramping at 10° C./min to 800° C.), and (c) 150° C. (weight of sample: 13.0043 mg; ramping at 10° C./min to 800° C. in N₂);

FIG. 8 shows the XRD pattern of treated ITO nanoparticles and surface modified ITO nanoparticles at 50° C., 100° C. and 150° C.;

FIG. 9 shows a schematic representation of in-situ diffuse reflection infrared fourier transform spectroscope (DRIFT);

FIGS. 10(a) and (b) shows the kinetic spectra of the ITO nanoparticles reacting with acetylene at room temperature, and with ITO in air/N₂ at room temperature as background;

FIG. 11 shows the XPS spectra of the O 1s core level for the commercial ITO films (a) after cleaning, (b) after O₂ plasma, and (c) after reaction with acetylene;

FIG. 12 shows the XPS spectra of the C 1s core level for the commercial ITO films (a) after cleaning, (b) after O₂ plasma, and (c) after reaction with acetylene; and

FIG. 13 shows (a) the optimised interface structure between two acetylene-modified nanoparticles and (b) the calculated electron density of states showing a metallic band structure upon cross-linking.

### DETAILED DESCRIPTION OF THE INVENTION

The exemplary embodiments aim to provide a simple and scalable method for preparing transparent conducting oxide (TCO) films. The TCO films prepared from the method of the present invention have high film stability and low resistivity which is an improvement over TCO films prepared solely by the deposition of TCO nanoparticles on flexible substrates by physical vapour deposition techniques.

The method of the present invention provides a viable technology to enable large scale, low temperature thin film and device fabrications of TCOs, especially on temperature sensitive flexible substrates. The deposition technology developed in this invention is scalable, low cost and can be extended to thin film growth of essentially all TCO nanoparticles.

In general terms, the present invention relates to a method of preparing thin films. In particular, the thin films are thin films of TCO nanoparticles. The advantage of the method of the invention is that the thin films may be prepared at low temperature and may therefore be used for preparing thin films on temperature sensitive flexible substrates.

The invention also relates to TCO nanoparticles, wherein the TCO nanoparticles are surface-modified by at least one unsaturated moiety. This may have the advantage of enhancing the electron hopping between the nanoparticles, leading to lower resistivity.

According to a first aspect, there is a provided a method of preparing a transparent conducting oxide (TCO) film, comprising:
applying surface modified TCO nanoparticles onto a surface of a substrate; and
cross-linking the surface modified TCO nanoparticles.

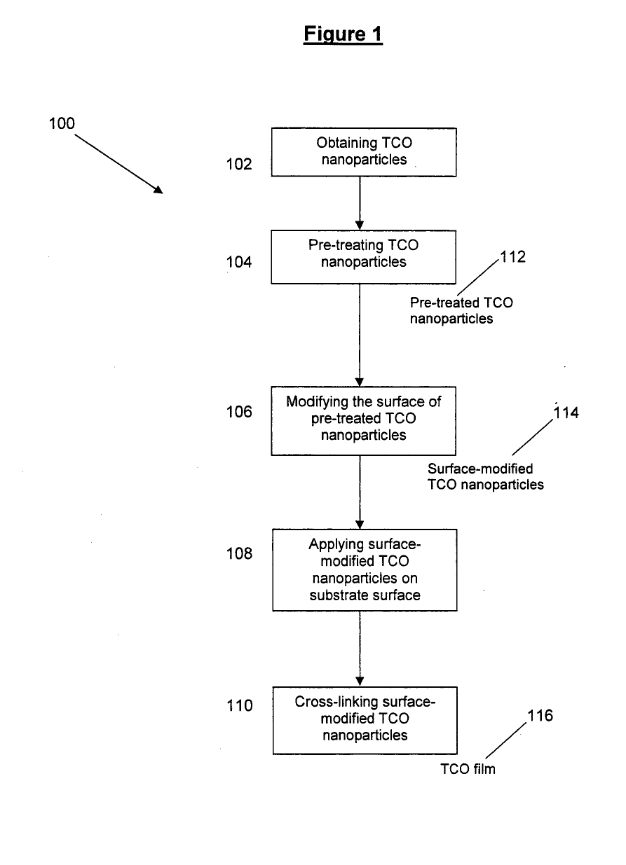

The method 100 for preparing the TCO film may generally comprise the steps as shown in FIG. 1. Each of these steps will now be described in more detail.

Step 102 comprises obtaining TCO nanoparticles. The TCO nanoparticles may be any suitable TCO nanoparticle. For example, the step 102 may comprise obtaining TCO nanoparticles which may be, but are not limited to indium tin oxide (ITO), zinc oxide (ZnO), TiO₂, Fe₂O₃, ZrO₂, SnO₂, In₂O₃, CuO, or a combination thereof. Further TCO nanoparticles known or obvious to a skilled person are also encompassed by the scope of the present invention. According to a particular embodiment, the step 102 may comprise obtaining indium tin oxide (ITO) nanoparticles.

For the purposes of the present invention, a TCO nanoparticle is defined as being one which has at least one dimension in the nanoscale. The step 102 of obtaining TCO nanoparticles may comprise obtaining TCO nanoparticles of any suitable size. For example, the TCO nanoparticles obtained in step 102 may comprise at least one dimension of size ≦200 nm. In particular, the TCO nanoparticles obtained in step 102 may comprise at least one dimension of size 3-150 nm, 5-100 nm, 10-75 nm, 15-60 nm, 20-50 nm, 25-45 nm, 30-35 nm. Even more in particular, the TCO nanoparticles obtained in step 102 may comprise at least one dimension of size 3-25 nm, more particularly 10-25 nm. For the purposes of the present invention, the dimension may refer to the average diameter of the TCO nanoparticle obtained in step 102.

Step 104 comprises pre-treating the TCO nanoparticles obtained from step 102 to obtain pre-treated TCO nanoparticles 112. The step 104 of pre-treating the TCO nanoparticles may be an optional step. The step 104 of pre-treating enables higher quality surface modification to be achieved in subsequent step 106 of the method 100. In particular, the step 104 of pre-treating removes surface impurities, such as surface hydrocarbon species on the surface of the TCO nanoparticles which may arise during the synthesis process of the TCO nanoparticles in organic solvents, thereby achieving a cleaner surface modification in step 106. The step 104 of pre-treating may comprise any suitable pre-treatment to obtain pre-treated TCO nanoparticles 112. For example, the step 104 of pre-treating may comprise heating the obtained TCO nanoparticles from step 102. The heating may be carried out at any suitable temperature. For example, the heating may be carried out at a temperature of 250-550° C., 300-500° C., 320-470° C., 340-450° C., 350-400° C., 370-380° C. In particular, the heating may be carried out at a temperature of 300-350° C. Even more in particular, the heating may be carried out at a temperature of 350° C. According to a particular embodiment, the obtained TCO nanoparticles from step 102 may be pre-treated by being calcined in argon at 350° C.

The pre-treated TCO nanoparticles 112 obtained from step 104 are then subjected to a step 106 of modifying the surface of the pre-treated TCO nanoparticles 112 to obtain surface-modified TCO nanoparticles 114. The step 106 of modifying may comprise any suitable process to modify the surface of the pre-treated TCO nanoparticles 112. The pre-treated TCO nanoparticles 112 may be modified to confer certain properties onto the TCO nanoparticles. Surfaces of TCO nanoparticles, such as those described above are covered extensively by oxygen dimers, along with isolated oxygen atoms, upon exposure to O₂ gas. Electron hopping between TCO nanoparticles is therefore difficult since the surfaces of the TCO nanoparticle are electron abundant due to the coverage of the oxygen atoms on the surface of the TCO nanoparticles. The low electron hopping rate gives rise to poor electrical conductivity of the TCO nanoparticles. Therefore, after the step 106 of modifying the surface of the pre-treated TCO nanoparticles 112, the surface of the pre-treated TCO nanoparticles 112 may become positively charged with an improved conductivity.

The step 106 of modifying may comprise any suitable process. For example, the step 106 of modifying may comprise any process which enables the surface of the pre-treated TCO nanoparticles 112 to become positively charged. In particular, the step 106 of modifying may comprise reacting the pre-treated TCO nanoparticles 112 with at least one unsaturated moiety to obtain surface-modified TCO nanoparticles 114. Even more in particular, the step 106 of modifying may comprise heating the pre-treated TCO nanoparticles 112 with at least one unsaturated moiety to obtain surface-modified TCO nanoparticles 114. The heating may be carried out under suitable conditions and at a suitable temperature. For example, the heating may be carried out at a temperature of 50-250° C., 75-200° C., 100-175° C., 125-150° C. According to a particular embodiment, the heating may be carried out at a temperature of about 50° C., 100° C. or 150° C.

The heating may be carried out for a pre-determined period of time. For example, the heating may be carried out for 15 minutes to 3 hours, 30 minutes to 2.5 hours, 45 minutes to 2 hours, 1 hour to 1.5 hours. In particular, the heating may be carried out for 1 hour.

The unsaturated moiety may be any suitable unsaturated moiety. For the purposes of this invention, an unsaturated moiety will be defined as a moiety which comprises one or more pi-bond. For example, the unsaturated moiety suitable for the purposes of the present invention may be optionally substituted alkenes, alkynes, dienes, an aromatic compound, a heteroaromatic compound, or a combination thereof. For the purposes of the present invention, a heteroaromatic compound will be defined as an aromatic compound which contains heteroatoms such as O, N or S, as part of the cyclic conjugated pi-system.

In particular, the unsaturated moiety may be represented by the formula (I):

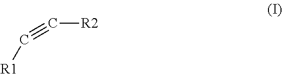

wherein each R1 and R2 may be the same or different, and may be selected from the group consisting of: H, an aliphatic species, an aromatic species and a halide.

The aliphatic species may comprise aliphatic hydrocarbon groups such as a methyl group, trifluoromethyl group, ethyl group, propyl group, isopropyl group, butyl group, isobutyl group, sec-butyl group, tert-butyl group, pentyl group, isopentyl group, neopentyl group, tert-pentyl group, 1-methylpentyl group, 2-methylpentyl group, hexyl group, isohexyl group, 5-methylhexyl group, heptyl group, and octyl group. In particular, the aliphatic species may be a methyl group (CH₃—).

The aromatic species may comprise aromatic hydrocarbon groups such as a phenyl group, biphenylyl group, o-tolyl group, m-tolyl group, p-tolyl group, xylyl group, mesityl group, o-cumenyl group, m-cumenyl group, and p-cumenyl group. In particular, the aromatic species may be a phenyl group (C₆H₅—).

The halide may be any suitable halide group such as a fluoro group, chloro group, bromo group, and iodo group. In particular, the halide group may be chloro group (Cl—).

Even more in particular, the unsaturated moiety may be represented by the formula (I) in which R1 and R2 may be the same and may be H. According to a particular embodiment, the unsaturated moiety may be acetylene. According to another particular embodiment, the unsaturated moiety may be ethylene. According to yet another particular embodiment, the unsaturated moiety may be butadiene.

In particular, the unsaturated moiety may be represented by the formula (II):

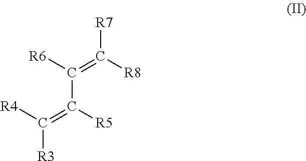

wherein each R3, R4, R5, R6, R7 and R8 may be the same or different, and may be selected from the group consisting of: H, an aliphatic species, an aromatic species and a halide. Each of the aliphatic species, aromatic species and halide may be as described above.

Even more in particular, the unsaturated moiety may be represented by the formula (II) in which each of the R3, R4, R5, R6, R7 and R8 may be the same and may be H.

During the step 106 of modifying, the oxygen dimers covering the surfaces of the pre-treated TCO nanoparticles 112 react with the unsaturated moiety. In particular, the oxygen dimers may undergo a [2+2] cycloaddition reaction when reacted with the unsaturated moiety such as acetylene or ethylene. The surface reactions may be highly exothermic with no activation barriers. Accordingly, the top surface of the surface-modified TCO nanoparticles 114 consist of positively charged species since the underneath oxygen atoms withdraw electrons from the unsaturated moiety. Electron hopping between the surface-modified TCO nanoparticles 114 is therefore significantly enhanced, leading to lower resistivity and higher conductivity.

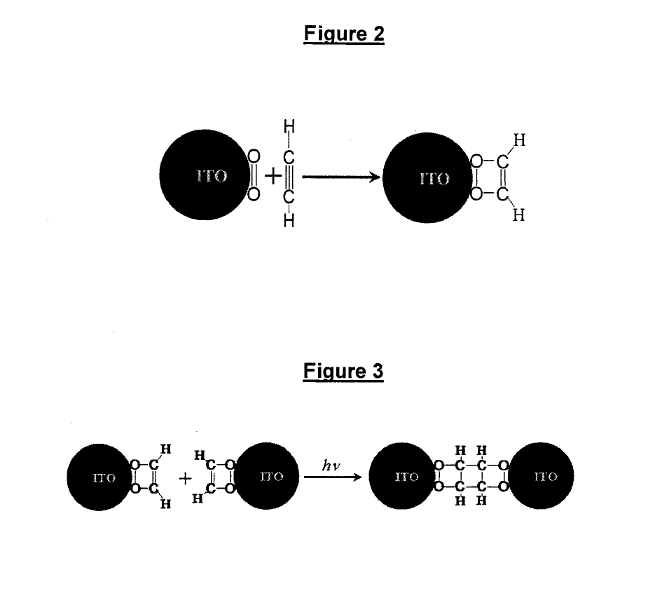

According to a particular embodiment, when the unsaturated moiety is acetylene, a C═C bond is formed upon a cycloaddition reaction with an oxygen dimer on the surface of a pre-treated TCO nanoparticle 112, as shown in FIG. 2.

The surface-modified TCO nanoparticles 114 may then be applied on a substrate surface according to step 108. The step 108 of applying may comprise any suitable method of applying the surface-modified TCO nanoparticles 114 on the surface of a substrate. For example, the step 108 of applying may be by any suitable deposition method. The step 108 of applying may comprise chemical deposition or physical deposition of the surface-modified TCO nanoparticles 114 on a substrate surface. In particular, the step 108 of applying may comprise wet chemistry, spin coating, spray coating, roller coating, chemical solution deposition, chemical vapour deposition, plasma-enhanced chemical vapour deposition, thermal evaporator, electron beam evaporator, sputtering, pulsed laser deposition, cathodic arc deposition, physical vapour deposition, electrohydrodynamic deposition, molecular beam epitaxy, spin on glass (SOG) or a combination thereof, of the surface-modified TCO nanoparticles 114 on a substrate surface. The step 108 of applying may be carried out under conditions suitable for the purposes of the present invention.

The substrate on which the surface-modified TCO nanoparticles 114 may be applied in step 108 may be any suitable substrate for the purposes of the present invention. For example, the substrate may be a plastic or glass substrate. In particular, the substrate may be a temperature sensitive flexible substrate. Even more in particular, the substrate may be a temperature sensitive flexible plastic substrate. For example, the plastic substrate may be a substrate containing polypropylene, polycarbonate, polyimide, polyethersulfone, polyethylene terephthalate or a mixture thereof.

The method 100 further comprises a step 110 of cross-linking the surface-modified TCO nanoparticles 114 which have been applied on a surface of a substrate to form a TCO film 116. The step 110 of cross-linking may comprise any suitable method of cross-linking for the purposes of the present invention. For example, the step 110 of cross-linking may comprise cycloaddition, photochemical reaction, thermal reaction, or a combination thereof. The step 110 of cross-linking will enhance the stability and processability of the TCO film 116 formed. The design and development of polarized flexible substrates may significantly induce strong adhesion of the cross-linked surface-modified TCO nanoparticles on the substrates.

In particular, the step 110 of cross-linking may comprise a photochemical reaction. The photochemical reaction may be activated by injecting photons or by exposing the surface-modified TCO nanoparticles which are applied to the substrate surface to UV light, thereby cross-linking the surface-modified TCO nanoparticles 114 which have been applied on the surface of the substrate. The cross-linking between the surface-modified TCO nanoparticles 114 may be via covalent bonds. According to a particular embodiment, a [2+2] cycloaddition between two C═C bonds residing separately in two neighbouring surface-modified TCO nanoparticles 114 which have been applied on a substrate surface may be thermally forbidden but optically allowed. The reaction is therefore activated by a photochemical reaction. The photochemical reaction may be as described above. In particular, the reaction may be activated by injecting photons upon coating of ITO nanoparticles which have been surface-modified by acetylene on a temperature sensitive flexible substrate, leading to cross-linking among the ITO nanoparticles via covalent bonds, as shown in FIG. 3.

The TCO film 116 may have desirable properties. The TCO film 116 is sufficiently stable for use in flexible optoelectronic devices. The TCO film 116 may be an anti-reflection layer. The TCO film 116 may have a suitable thickness. In particular, the TCO film 116 may be a thin TCO film. For example, the TCO film 116 may have a thickness between 5 nm to 1 mm. In particular, the TCO film 116 may have a thickness of less than 500 nm, 400 nm, 300 nm, 200 nm, 100 nm, 50 nm, 25 nm, 20 nm, 15 nm, 10 nm or 5 nm. The. TCO film 116 may be a single layer or multiple layers, and wherein each layer of the TCO film 116 may be the same or different from the other layer.

The method 100 is a scalable method. In particular, the method 100 may be suitable and scalable for a high volume roll-to-roll processing operation. Even more in particular, the method 100 may be suitable for fabricating thin films of ITO nanoparticles with high stability and low resistivity at a low temperature on flexible substrates. The method 100 may be extended to other TCO nanoparticles since TCO nanoparticles may exhibit similar surface structures under oxygen-rich atmospheres.

According to another aspect of the present invention, there is a provided a transparent conducting oxide (TCO) film obtained from or obtainable by the method described above. The TCO film obtained may have desirable properties. In particular, the TCO film may be as described in relation to the TCO film 116.

The present invention further provides an article of manufacture comprising the TCO film 116. The article of manufacture may be any suitable article of manufacture which requires a TCO film. For example, the article of manufacture may comprise flexible optoelectronic devices. In particular, the article of manufacture may be, but not limited to, an organic light-emitting diode (OLED), a flat panel display, thin film solar cells, a flexible display, a touch panel, a transparent electrode for optoelectronic devices, a heat-reflecting mirror, or a transparent heating element.

There is also provided a transparent conducting oxide (TCO) nanoparticle including a surface modification by an unsaturated moiety. For example, the TCO nanoparticle including a surface modification by an unsaturated moiety may be the surface-modified TCO nanoparticle 114. The unsaturated moiety may be any suitable unsaturated moiety for the purposes of the present invention. In particular, the unsaturated moiety may be as described above. The TCO nanoparticle including the surface modification may be for use in a method of preparing a transparent conducting oxide film. For example, the method may be the method 100 as described above.

Having now generally described the invention, the same will be more readily understood through reference to the following examples which are provided by way of illustration, and are not intended to be limiting.

### EXAMPLES

### Example 1

Preparation of TCO Nanoparticles

For this example, indium-tin oxide (ITO) nanoparticles were synthesized as follows.

Indium (III) nitrate (Sigma-Aldrich, analytical grade) and tin (IV) chloride (Sigma-Aldrich, analytical grade) were dissolved in anhydrous ethanol (Sigma-Aldrich, analytical grade) to obtain a first solution. A stabilizer, beta-alanine (Sigma-Aldrich, analytical grade), was dissolved in ammonia solution (Sigma-Aldrich, analytical grade) to obtain a second solution. The first solution was then added drop wise into the second solution to obtain a third solution. The third solution was then refluxed for about 24 hours at 80° C. White solids were obtained. These white solids were then separated by centrifugation and washed several times with deionised water. The washed white solids were then dried overnight. Subsequently, the white solids were calcined at 350° C. in argon for about 3 hours to obtain the ITO nanoparticles.

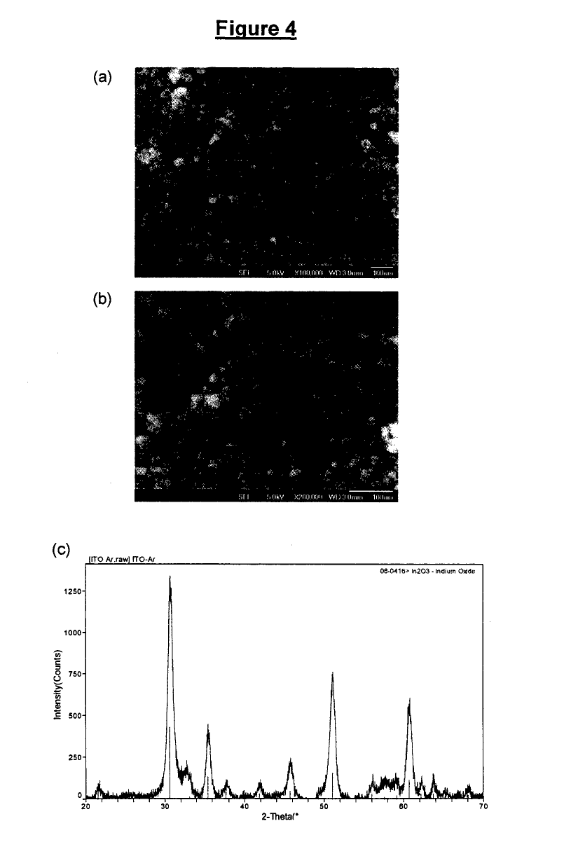

The obtained ITO nanoparticles were then characterized with Field Emission Scanning Electron Microscope (FESEM) (Jeol, 6710F) and by an x-ray diffraction (XRD) machine (Siemens, D5005). The SEM images and XRD pattern of the ITO nanoparticles are shown in FIG. 4.

In particular, the diffraction peaks shown in FIG. 4(c) are in good agreement with standard database for ITO nanoparticles. From the SEM images (FIGS. 4(a) and (b)), the size of the ITO nanoparticles was determined to be in the range of 10-25 nm in diameter.

Pre-Treatment of ITO Nanoparticles

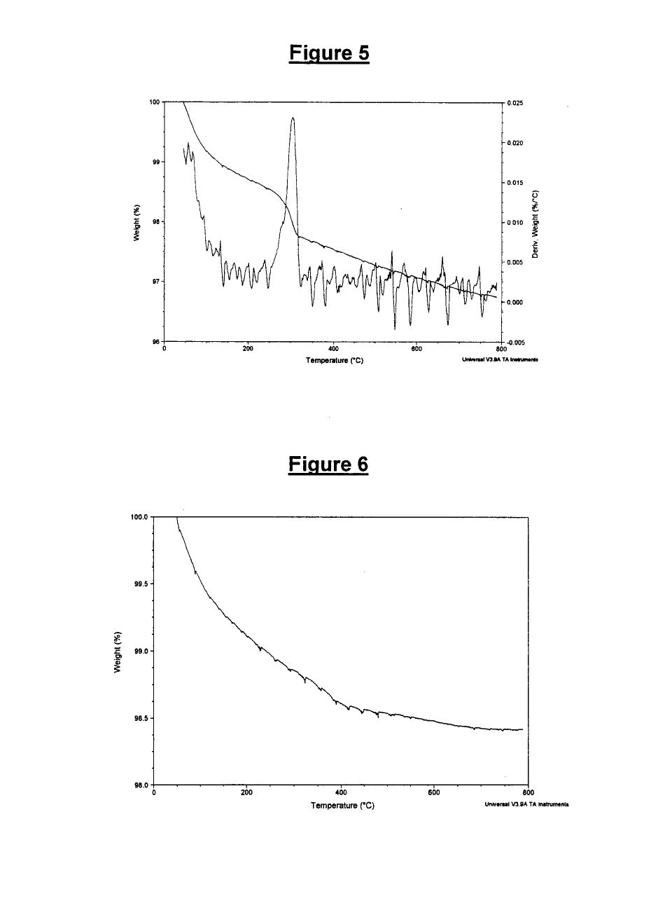

The ITO nanoparticles were then subjected to a pre-treatment. To determine the best pre-treatment conditions for the ITO nanoparticles, a thermogravimetric analysis and a differential thermal analysis (TGA-DTA) was carried out using a TA Instruments (SDT 2960) to simultaneously measure both heat flow and weight changes in the ITO nanoparticles as a function of temperature in a controlled environment. The results obtained from the analysis are as shown in FIG. 5.

From FIG. 5, it can be seen that there are two distinct weight losses. The first occurred at about 140° C. and the second occurred between 270° C. and 340° C. The first weight loss was mainly caused by desorption of water while the second weight loss was mainly attributed to desorption and decomposition of the organic molecules used as surfactants in the preparation of the ITO nanoparticles. It can also be seen from FIG. 5 that after 350° C., there was no obvious weight loss in the sample of the prepared ITO nanoparticles. Accordingly, the pre-treatment of the ITO nanoparticles was carried out at 350° C. under argon flow.

The pre-treatment was carried out in a tube furnace (2 inches quartz tube furnace −240V, Model no. W1108/MTIC) with argon flow in which the ITO nanoparticles were heated up to 350° C.

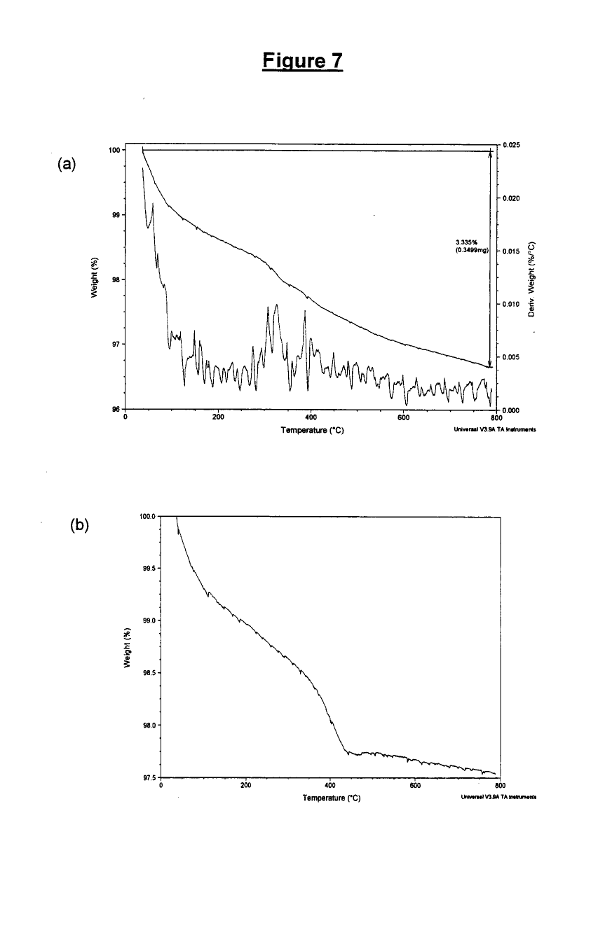

A second TGA analysis was carried out for the ITO nanoparticles after the nanoparticles had undergone the pre-treatment. The results are shown in FIG. 6. It can be seen from the results that there was no obvious weight loss throughout the heating process, implying that the surfaces of the treated ITO nanoparticles were clean after the pre-treatment.

Surface Modification of the Treated ITO Nanoparticles

Surface modification of the treated ITO nanoparticles was then carried out using an unsaturated moiety. The unsaturated moiety used for the surface modification was acetylene (Sigma-Aldrich, analytical grade). The surface modifications were made to be a continuous process from the pre-treatment so that acetylene gas could be introduced into the tube furnace after the completion of the pre-treatment of the ITO nanoparticles without opening the tube furnace.

In particular, after the pre-treatment, the ITO nanoparticles were separated into three batches. The ITO nanoparticles of each of the three batches were cooled down to a temperature of about 25° C. Subsequently, the three batches were subjected to the surface modification by being heated up to 50° C., 100° C. and 150° C., respectively, under acetylene for about 1 hour.

A TGA analysis of the surface-modified ITO nanoparticles from each of the three batches was then carried out. The results are shown in FIGS. 7(a) to (c). Compared to FIG. 5, a weight loss between 300° C. and 350° C. was observed, corresponding to the desorption of the acetylene molecules chemisorbed on the surfaces of the ITO nanoparticles upon reacting with oxygen dimers present on the surface of the ITO nanoparticles. In particular, the loss in the weight of the sample of ITO nanoparticles became more pronounced as the temperature at which the surface modification was carried out was increased since an elevated temperature was required to break the C—O bonds formed upon the [2+2] cycloaddition during the surface modification of the ITO nanoparticles.

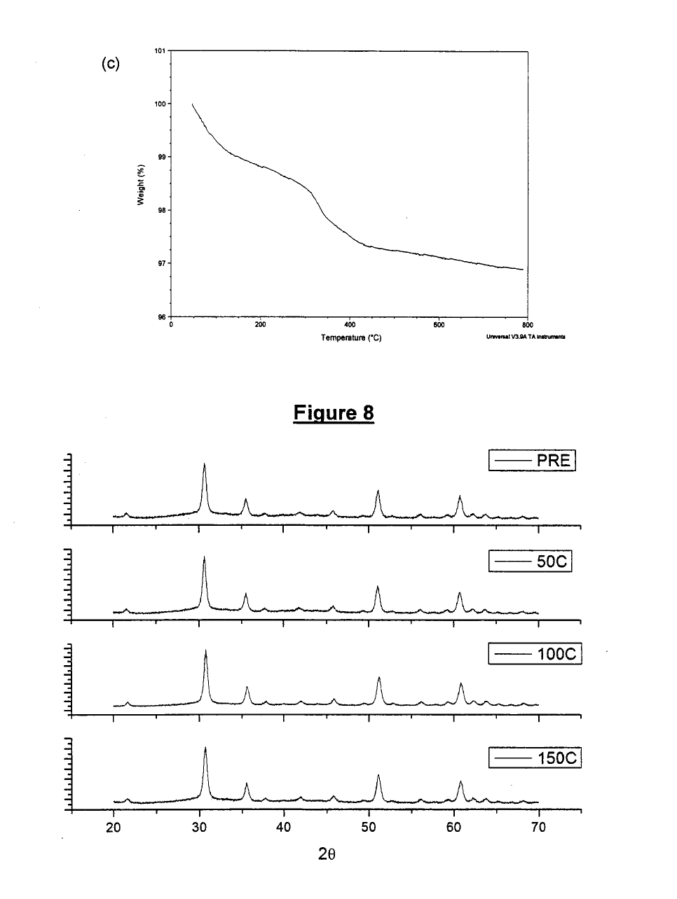

A XRD pattern to compare the patterns of the treated ITO nanoparticles and surface-modified ITO nanoparticles was also obtained. The results are shown in FIGS. 8(a) to (d). It can be seen that the peak positions as well as the diffraction patterns of the surface-modified ITO nanoparticles remained the same as that of the treated ITO nanoparticles. This indicates that the surface modifications of the ITO nanoparticles did not give rise to a change of lattice structure in the nanoparticles. This is consistent with the TGA results shown in FIG. 7, which indicate that the weight loss between 300° C. and 350° C. is attributed to the desorption of acetylene molecules chemisorbed on the ITO nanoparticle surfaces but not to the content of the ITO nanoparticles.

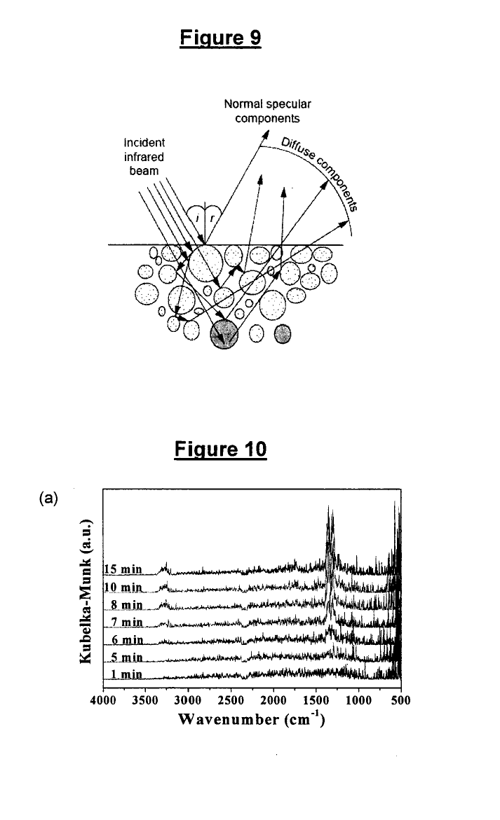

The [2+2] cycloaddition reaction between the treated ITO nanoparticles and acetylene was confirmed using an in-situ Diffuse Reflection Infrared Fourier Transform spectroscope (DRIFT) (Digilab, Excalibur FTS-3000). The device is schematically shown in FIG. 9. The test as carried out was as follows.

A sample of the treated ITO nanoparticles was heated up in N₂/air. The sample was then cooled to room temperature in N₂/N₂. The background of the treated ITO nanoparticles was recorded in N₂/air. Subsequently, the sample of treated ITO nanoparticles was exposed to acetylene and the kinetic spectra were recorded.

The results obtained are shown in FIGS. 10(a) and (b). The results show that the carbon-carbon triple bond becomes a double bond upon cycloaddition reaction as the C—C and C—H bond stretching frequencies become increasingly visible with reaction time.

### Example 2

Comparison with Commercial ITO Films

X-ray photoelectron spectroscopy (XPS) experiments were carried out for commercially available ITO/glass films to demonstrate the [2+2] cycloaddition reaction. The commercially available ITO/glass samples were chosen because they have the same crystalline structure as the ITO nanoparticles prepared in example 1. They also avoid the charging effect, which is commonly observed in XPS measurement for powder samples. The experimental procedure was as follows.

Three commercial ITO/glass films (Sigma-Aldrich) were cleaned using piranha solution (H₂SO₄:H₂O₂=7:3, by volume) (Sigma-Aldrich, analytical grade), DI water and anhydrous ethanol (Sigma-Aldrich, analytical grade) successively. The freshly cleaned ITO/glass films were treated with O₂ plasma for 10 minutes in a chamber having a pressure of about 440-460 mTorr. The freshly treated ITO/glass films were then made to react with acetylene gas for 100° C. for 30 minutes.

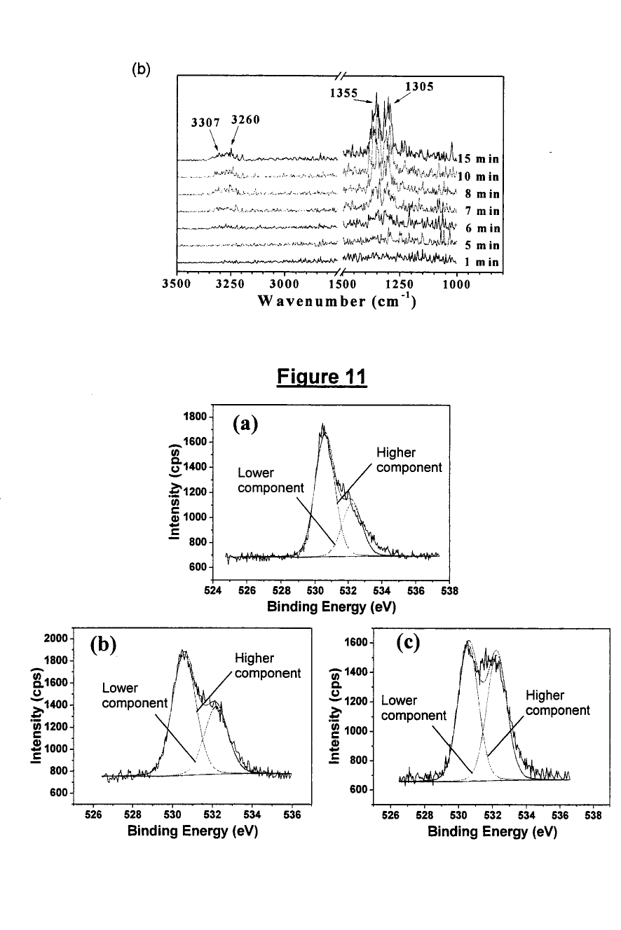

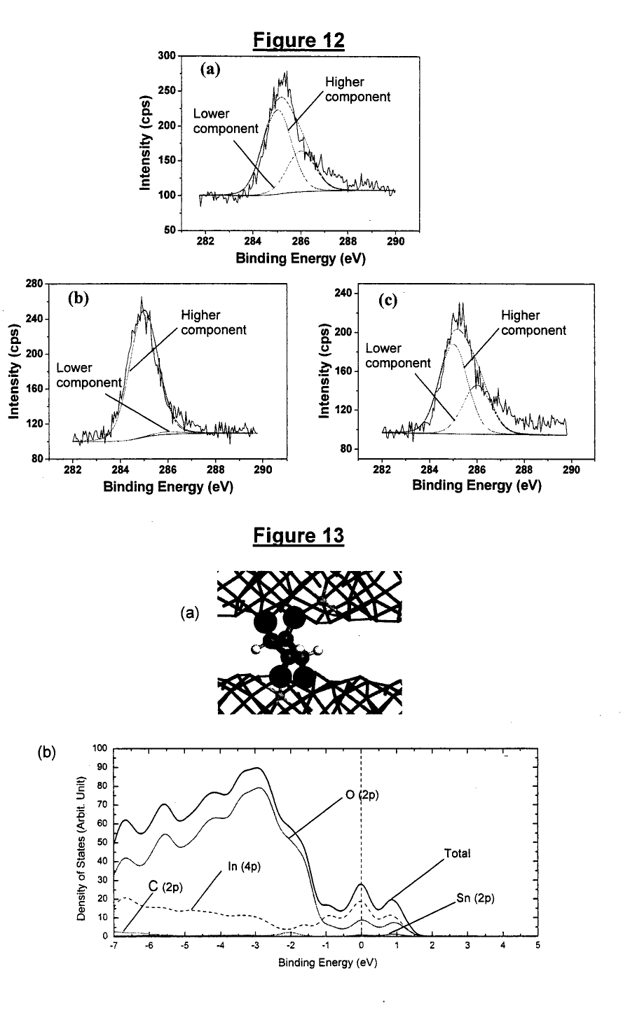

FIGS. 11 and 12 show the corresponding O 1s and C 1s core level spectra of the three ITO/glass samples. Deconvolution of the obtained core level spectra was performed to identify the bonding states of each element near the surface region. A Shirley back-ground subtraction was applied and Laurentzian-Gaussian ratio was fixed at 10%. Full width at half maximum (FWHM) was fixed at 1.4 eV.

After peak fitting, two components in O 1s spectra were obtained with one centred at about 530.58 eV and the other at about 532.23 eV. The lower peak fitting is attributed to lattice oxygen. However, the higher peak is superimposed by O—H, O—C and (O₂)²⁻. By comparing the peak area of the higher component to the lower one, the ratios for all three samples shown in FIGS. 11(a), (b) and (c) obtained was 0.43, 0.56 and 0.92, respectively. O—H and O—C are energetically unfavourable under highly reactive oxygen radical induced by oxygen plasma. Therefore, this ratio increased from 0.43 to 0.56 after oxygen plasma treatment due to the formation of more oxygen dimers (O₂)²⁻ on the ITO nanoparticle surface. Upon reacting with acetylene, the ratio was further increased. This was due to the formation of new O—C bonds as the result of the reaction between the surface oxygen dimers on the ITO nanoparticles and the acetylene molecules.

The same peak fitting was performed for the Cis core level XPS spectra, except that peak positions were fixed at 285 and 286 eV, respectively. The 285 eV C 1s peak was widely accepted as the aliphatic carbon contaminations and 286 eV C 1S peak was attributed to the carbon connected with oxygen via a single covalent bond as the consequence of the [2+2] cycloaddition. The ratios of the higher component to the lower component were measured to determine the evolution of the core level shift. As shown in FIGS. 12(a), (b) and (c), carbon contaminations existed on the surface of the ITO nanoparticles after the basic cleaning procedures. However, upon oxygen plasma treatment, the ratio decreased from 0.48 to 0.01, indicating the complete removal of the higher C 1s peak. The existing 285 eV peak was due to the aliphatic carbon contamination in air because of the inevitable exposure of the ITO/glass films to air after oxygen plasma treatment. Upon the reaction of the ITO sample with acetylene, the ratio was increased to 0.54, implying the formation of new Co—O species, which is consistent with the O 1s XPS results.

The results demonstrate that O₂ dimers can be readily formed on ITO surfaces and [2+2] cycloaddition reaction between the O₂ dimers and acetylene molecules can easily occur.

### Example 3

The fully optimised structure at the interface between two neighbouring ITO nanoparticles after undergoing a cross-linking step following surface modification is shown in FIG. 13(a). The electronic density of states was also calculated by simulation. The results of the simulation are shown in FIG. 13(b). The results show a strong metallic band character (see FIG. 13(b)) indicating good conductivity upon nanoparticle cross-linking. With the strong metallic character of the band structure and cross-link between ITO nanoparticles via covalent bonds, it is anticipated that the surface reaction will significantly enhance the film sheet-conductivity, stability and processability.

Whilst the foregoing description has described exemplary embodiments, it will be understood by those skilled in the technology concerned that many variations in details of design, construction and/or operation may be made without departing from the present invention.

1. A method of preparing a transparent conducting oxide (TCO) film, comprising:
reacting TCO nanoparticles with at least one unsaturated moiety to provide surface modified TCO nanoparticles;
applying the surface modified TCO nanoparticles onto a surface of a substrate; and
cross-linking the surface modified TCO nanoparticles.

2. (canceled)

3. The method according to claim 1, wherein the reacting comprises heating the TCO nanoparticles with the unsaturated moiety.

4. The method according to claim 3, wherein the heating is carried out at a temperature of 50-250° C.

5. The method according to claim 1, wherein the TCO nanoparticles comprise at least one dimension of size ≦200 nm.

6. (canceled)

7. The method according to claim 1, wherein the unsaturated moiety is a moiety which comprises one or more pi-bond.

8. The method according to claim 7, wherein the unsaturated moiety is selected from the group consisting of: optionally substituted alkene, alkyne and diene.

9. The method according to claim 1, wherein the unsaturated moiety is represented by the formula (I): 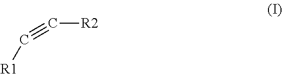
wherein each R1 and R2 is the same or different and is selected from the group consisting of: H, an aliphatic species, an aromatic species and a halide.

10. The method according to claim 9, wherein the aliphatic species is CH₃—, the aromatic species is C₆H₅—, or the halide is Cl.

11. The method according to claim 9, wherein each R1 and R2 is the same and is H.

12. The method according to claim 1, wherein the unsaturated moiety is represented by the formula (II): 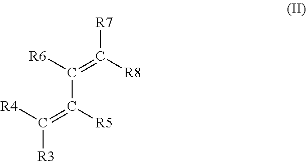
wherein each R3, R4, R5, R6, R7 and R8 is the same or different and is selected from the group consisting of: H, an aliphatic species, an aromatic species and a halide.

13. The method according to claim 12, wherein the aliphatic species is CH₃—, the aromatic species is C₆H₅—, or the halide is Cl.

14. The method according to claim 12, wherein each R3, R4, R5, R6, R7 and R8 is the same and is H.

15. The method according to claim 1, wherein the unsaturated moiety is acetylene, ethylene, butadiene or a combination thereof.

16. The method according to claim 1, further comprising heating the TCO nanoparticles prior to reacting them with at least one unsaturated moiety.

17. (canceled)

18. The method according to claim 1, wherein the cross-linking is by cycloaddition, photochemical reaction and/or thermal reaction.

19. (canceled)

20. The method according to claim 1, wherein the applying is by spin coating, spray coating, roller coating, chemical deposition, physical vapour deposition, or a combination thereof.

21. A transparent conducting oxide (TCO) film obtained from the method according to claim 1.

22. The TCO film according to claim 21, wherein the TCO film is comprised in an article of manufacture.

23. (canceled)

24. A transparent conducting oxide (TCO) nanoparticle including a surface modification by an unsaturated moiety.

25. The TCO nanoparticle according to claim 24, wherein the unsaturated moiety is a moiety which comprises one or more pi-bond.

26. (canceled)
